(19) United States
(12) Patent Application Publication
(10) Pub. No.: US 2025/0212492 A1
(43) Pub. Date: Jun. 26, 2025

(54) SEMICONDUCTOR DEVICE INCLUDING FERROELECTRIC TUNNEL BARRIER LAYER

(71) Applicant: SK hynix Inc., Icheon-si (KR)

(72) Inventor: Won Tae KOO, Icheon-si (KR)

(21) Appl. No.: 18/668,148

(22) Filed: May 18, 2024

(30) Foreign Application Priority Data
Dec. 20, 2023 (KR) 10-2023-0187251

(51) Int. Cl. H01L 29/51; G11C 11/22; H01L 21/28; H10B 51/30; H10B 53/30

(52) U.S. Cl. CPC H10D 64/689; G11C 11/2275; H10D 64/033; H10B 51/30; H10B 53/30

(57) ABSTRACT

A semiconductor device according to an aspect includes a first electrode layer, a ferroelectric tunnel barrier layer disposed over the first electrode layer, and a second electrode layer disposed over the ferroelectric tunnel barrier layer. The ferroelectric tunnel barrier layer includes oxygen vacancies. The second electrode layer includes a metal oxide. The second electrode layer has a relatively low density of conducting carriers, compared to the first electrode layer.

### CROSS-REFERENCE TO RELATED APPLICATION

The present application claims priority under 35 U.S.C. § 119 (a) to Korean Application No. 10-2023-0187251, filed on Dec. 20, 2023 in the Korean Intellectual Property Office, which is incorporated herein by reference in its entirety.

### BACKGROUND

### 1. Technical Field

The present disclosure generally relates to a semiconductor device including a ferroelectric tunnel barrier layer.

### 2. Related Art

A ferroelectric material refers to a material having spontaneous electrical polarization in a state in which an external electric field is not applied. The spontaneous electrical polarization may be implemented as, for example, a pair of remanent polarization states having different orientations. The pair of remanent polarization states may be switched by application of an external electric field. The polarization characteristics of the ferroelectric material may be used to store signal information of “0” and “1” in a non-volatile manner.

As an example, research is being conducted on ferroelectric material as a dielectric layer of a cell capacitor. As another example, research is being conducted on the use of ferroelectric material as a gate dielectric layer of a transistor as a memory element in a structure. In addition, research is being conducted on the use of a ferroelectric tunnel barrier layer as a memory element in a tunnel barrier device in which a ferroelectric tunnel barrier layer is disposed between a pair of electrodes.

### SUMMARY

A semiconductor device according to an embodiment of the present disclosure may include a first electrode layer, a ferroelectric tunnel barrier layer disposed over the first electrode layer, and a second electrode layer disposed over the ferroelectric tunnel barrier layer. The ferroelectric tunnel barrier layer includes oxygen vacancies. The second electrode layer includes a metal oxide. The second electrode layer has a relatively low density of conducting carriers, compared to the first electrode layer.

A semiconductor device according to another embodiment of the present disclosure may include a first electrode layer, a ferroelectric tunnel barrier layer disposed over the first electrode layer, an oxygen reservoir layer disposed over the ferroelectric tunnel barrier layer, and a second electrode layer disposed over the oxygen reservoir layer.

A semiconductor device according to another embodiment of the present disclosure may include a first electrode layer, a ferroelectric tunnel barrier layer disposed over the first electrode layer, and a second electrode layer including a metal oxide disposed over the ferroelectric tunnel barrier layer. The ferroelectric tunnel barrier layer may include a first ferroelectric portion including oxygen vacancies of a first concentration, and a second ferroelectric portion including oxygen vacancies of a second concentration higher than the first concentration.

### BRIEF DESCRIPTION OF THE DRAWINGS

FIG. 1 is a cross-sectional view schematically illustrating a semiconductor device according to an embodiment of the present disclosure.

FIGS. 2 and 3 are views schematically illustrating an operation of a semiconductor device according to an embodiment of the present disclosure.

FIG. 4 is a cross-sectional view schematically illustrating a semiconductor device according to another embodiment of the present disclosure.

FIGS. 5 and 6 are views schematically illustrating an operation of a semiconductor device according to another embodiment of the present disclosure.

FIG. 7 is a cross-sectional view schematically illustrating a semiconductor device according to yet another embodiment of the present disclosure.

FIGS. 8 and 9 are views schematically illustrating an operation of a semiconductor device according to an embodiment of the present disclosure.

FIG. 10 is a cross-sectional view schematically illustrating a semiconductor device according to yet another embodiment of the present disclosure.

FIG. 11 is a cross-sectional view schematically illustrating a semiconductor device according to yet another embodiment of the present disclosure.

FIG. 12 is a cross-sectional view schematically illustrating a semiconductor device according to still another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong. In addition, expression of a singular form of a word should be understood to include the plural forms of the word unless clearly used otherwise in the context.

In this specification, a write operation of a semiconductor device may refer to an operation of applying a write voltage to a ferroelectric tunnel barrier layer to form remanent polarization having a predetermined orientation in the ferroelectric tunnel barrier layer and generating or removing a conductive protrusion in the ferroelectric tunnel barrier layer at the same time. The remanent polarization may be stored non-volatilely in the ferroelectric tunnel barrier layer as signal information. In addition, in this specification, a read operation of the semiconductor device may refer to an operation of applying a read voltage of a level that does not change the orientation of the remanent polarization stored in the ferroelectric tunnel barrier layer and measuring a tunneling current passing through the ferroelectric tunnel barrier layer. Based on the measured tunneling current, the signal information stored in the ferroelectric tunnel barrier layer can be read. That is, the semiconductor device according to an embodiment of the present disclosure may be a ferroelectric tunnel barrier device.

In this specification, “on state” may refer to an electrically conductive state exhibited by the ferroelectric tunnel barrier layer of the semiconductor device. The electrically conductive state may be caused by a rapid increase in tunneling current passing through the ferroelectric tunnel barrier layer. Conversely, “off state” may refer to an electrically insulating state exhibited by the ferroelectric tunnel barrier layer of the semiconductor device. In the electrically insulating state, the tunneling current passing through the ferroelectric tunnel barrier layer may be reduced or suppressed.

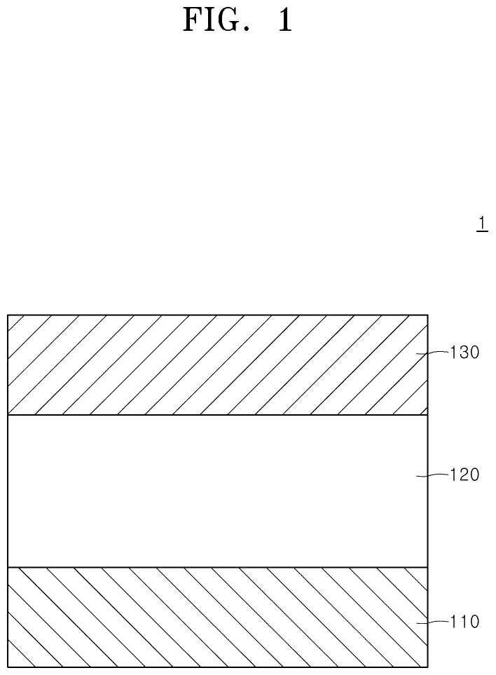

FIG. 1 is a cross-sectional view schematically illustrating a semiconductor device according to an embodiment of the present disclosure. Referring to FIG. 1, a semiconductor device 1 may include a first electrode layer 110, a ferroelectric tunnel barrier layer 120 disposed on the first electrode layer 110, and a second electrode layer 130 disposed on the ferroelectric tunnel barrier layer 120.

The first electrode layer 110 may include a conductive material. In an embodiment, the first electrode layer 110 may include an inert metal. As non-limiting examples, the inert metal may include gold (Au), platinum (Pt), ruthenium (Ru), iridium (Ir), and the like.

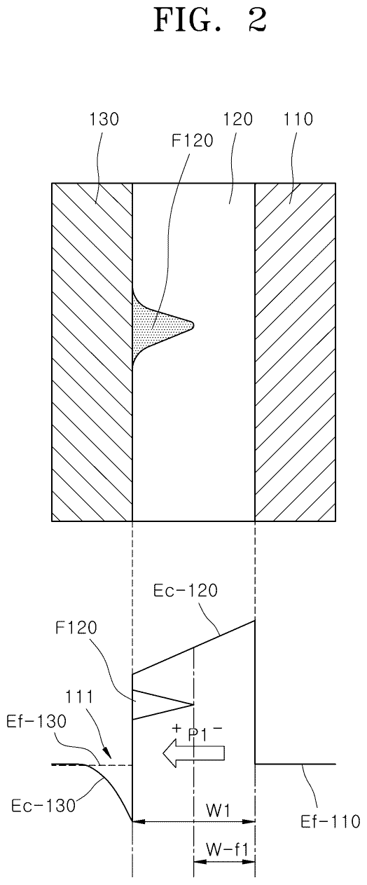

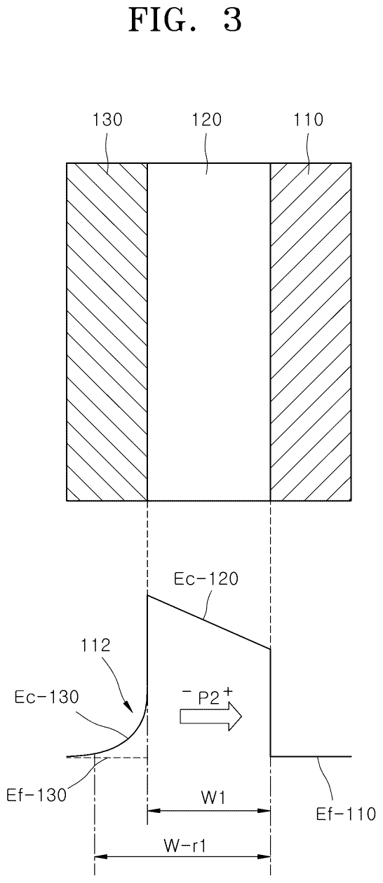

The ferroelectric tunnel barrier layer 120 may include a ferroelectric material having remanent polarization. The ferroelectric material may include, for example, hafnium oxide, zirconium oxide, hafnium zirconium oxide, or a combination of two or more thereof. In addition, the ferroelectric tunnel barrier layer 120 may have a thickness of about 1 nanometer (nm) to about 20 nm, for example. The ferroelectric tunnel barrier layer 120 may include oxygen vacancies that are movable by an electric field applied to the ferroelectric tunnel barrier layer 120 as described with reference to FIGS. 2 and 3.

The ferroelectric tunnel barrier layer 120 may have a pair of remanent polarization states having different polarization orientations. Depending on the orientation of the remanent polarization, characteristics of a tunneling current passing through the ferroelectric tunnel barrier layer 120 may change.

The second electrode layer 130 may include a conductive metal oxide. The conductive metal oxide may include, for example, ruthenium oxide (RuO₂), iridium oxide (IrO₂), platinum oxide (PtO₂), strontium ruthenium oxide (SrRuO₃), a metallic perovskite oxide, a conducting pyrochlore oxide, or a combination of two or more thereof. The metallic perovskite oxide may include, for example, niobium-doped strontium titanium oxide (Nb-doped SrTiO₃). The conductive pyrochlore oxide may include, for example, lead iridium oxide (Pb₂Ir₂O₇) or bismuth ruthenium oxide (Bi₂Ru₂O₇).

The second electrode layer 130 may have a relatively low density of electrons, which are conducting carriers, compared to the first electrode layer 110. In addition, in the region adjacent to the ferroelectric tunnel barrier layer 120, the density of conducting electrons of the second electrode layer 130 may be affected by the remanent polarization of the ferroelectric tunnel barrier layer 120. Accordingly, as will be described later with reference to FIGS. 2 and 3, due to the remanent polarization of the ferroelectric tunnel barrier layer 120, an electron accumulation region 111 or an electron depletion region 112 may be formed in an inner region of the second electrode layer 130 adjacent to an interface between the ferroelectric tunnel barrier layer 120 and the second electrode layer 130.

In an embodiment, the second electrode layer 130 may provide oxygen ions to the ferroelectric tunnel barrier layer 120. As will be described later with reference to FIG. 2, in response to oxygen ions that move into the ferroelectric tunnel barrier layer 120 under an external voltage, oxygen vacancies may accumulate in the ferroelectric tunnel barrier layer 120 to generate a conductive protrusion (F120 in FIG. 2).

As described above, a semiconductor device according to an embodiment of the present disclosure may include a ferroelectric tunnel barrier layer disposed between a first electrode layer and a second electrode layer. The ferroelectric tunnel barrier layer may include a ferroelectric material. A conductive protrusion of oxygen vacancies may be generated or removed in or from the ferroelectric tunnel barrier layer.

FIGS. 2 and 3 are views schematically illustrating an operation of a semiconductor device according to an embodiment of the present disclosure. A method of operating a semiconductor device may be described using a semiconductor device 1 of FIG. 1. Specifically, FIG. 2 is a view illustrating a first write operation in which the state of the semiconductor device 1 is converted into an electrical on-state. FIG. 2 may schematically illustrate an internal structure and energy band diagram of the semiconductor device 1 after the first write operation is completed. FIG. 3 is a view illustrating a second write operation in which the state of the semiconductor device 1 is converted into an electrical off-state. FIG. 3 may schematically illustrate the internal structure and energy band diagram of the semiconductor device 1 after the second write operation is completed.

Referring to FIG. 2, a predetermined first write voltage may be applied between the first electrode layer 110 and the second electrode layer 130 during the first write operation of the semiconductor device 1. The first write voltage may have a level sufficient to switch the polarization orientation of the ferroelectric material within the ferroelectric tunnel barrier layer 120. The first write voltage may be a voltage configured such that a bias applied to the second electrode layer 130 has a negative polarity and a bias applied to the first electrode layer 110 has a positive polarity.

Referring to FIG. 2, by the application of the first write voltage, polarization having a first polarization orientation P1 may be formed in the ferroelectric tunnel barrier layer 120. An electric field generated by the polarization may induce electrons to an inner region of the second electrode layer 130, adjacent to the interface between the ferroelectric tunnel barrier layer 120 and the second electrode layer 130, to form an electron accumulation region 111. In the electron accumulation region 111, the conduction band energy level Ec-130 of the second electrode layer 130 may be lower than the Fermi energy level Ef-130 of the second electrode layer 130. Accordingly, the second electrode layer 130 in the electron accumulation region 111 can result in sufficient electron density for tunneling. On the other hand, because the first electrode layer 110 has a higher electron density than the second electrode layer 130, an inner region of the first electrode layer 110, adjacent to the interface with the ferroelectric tunnel barrier layer 120 may be relatively less affected by the electric field generated by the polarization. Accordingly, an electron deficiency region might not be formed in the region of the first electrode layer 110 adjacent to the ferroelectric tunnel barrier layer 120. That is, there may be no change in the energy band diagram in the region of the first electrode layer 110, adjacent to the ferroelectric tunnel barrier layer 120.

Referring to FIG. 2, when the first write voltage is applied between the first electrode layer 110 and the second electrode layer 130, vacancies with positive charges may accumulate in the ferroelectric tunnel barrier layer 120 to form a conductive protrusion F120. The conductive protrusion F120 may extend from the interface between the second electrode layer 130 and the ferroelectric tunnel barrier layer 120, inside of the ferroelectric tunnel barrier layer 120, towards the first electrode layer 110. According to one of several hypotheses, the oxygen ions inside the second electrode layer 130 may be supplied into the ferroelectric tunnel barrier layer 120 by the first write voltage, and the oxygen vacancies inside the ferroelectric tunnel barrier layer 120 may move toward the second electrode layer 130 in a direction opposite to the conduction direction of the oxygen ions. After oxygen vacancies accumulate at the interface between the second electrode layer 130 and the ferroelectric tunnel barrier layer 120, the oxygen vacancies may grow inside the ferroelectric tunnel barrier layer 120 to generate the conductive protrusion F120. According to another hypothesis, due to the bias of a negative polarity (i.e., the first write voltage) applied to the second electrode layer 130, the oxygen vacancies distributed within the ferroelectric tunnel barrier layer 120 may move toward the second electrode layer 130. The oxygen vacancies that move to the second electrode layer 130 via the electrostatic attraction may accumulate at the interface between the second electrode layer 130 and the ferroelectric tunnel barrier layer 120, and then, may grow inside the ferroelectric tunnel barrier layer 120 to generate the conductive protrusion F120.

According to an embodiment of the present disclosure, the growth of the conductive protrusion F120 may be controlled so that the conductive protrusion F120 does not reach the first electrode layer 110. That is, the conductive protrusion F120 may maintain a non-contact state with the first electrode layer 110. The conductive protrusion F120 may be formed to be spaced apart from the first electrode layer 110. The growth of the conductive protrusion F120 may be controlled by controlling the application of the first write voltage. As an example, the first write voltage may be applied in the form of a pulse voltage, and the growth of the conductive protrusion F120 may be controlled by controlling the number of times the pulse voltage is applied. The conductive protrusion F120 may include oxygen vacancies having a positive charge, so that the conductive protrusion F120 may function as a conduction path for conducting carriers (e.g., electrons).

After forming the electron accumulation region 111 and the conductive protrusion F120 by controlled application of the first write voltage, the first write operation may be completed by removing the first write voltage. After the first write voltage is removed, a first remanent polarization state having a first polarization orientation P1 may be maintained in the ferroelectric tunnel barrier layer 120. Accordingly, the electron accumulation region 111 may be maintained in the second electrode layer 130. In addition, after the first write voltage is removed, the conductive protrusion F120 may be maintained within the ferroelectric tunnel barrier layer 120. Due to the conductive protrusion F120, the tunneling width of electrons that are tunneled for electrical conduction may be reduced from a first width W1, corresponding to the thickness of the ferroelectric tunnel barrier layer 120, to a first tunneling width W-f1. In FIGS. 2 and 3, a conduction band energy level of the ferroelectric tunnel barrier layer 120 is marked as Ec-120, and a Fermi energy level of the first electrode layer 110 is marked as Ef-110.

As described above, by performing a first write operation, a first remanent polarization state of a first polarization orientation P1 may be stored as first signal information in the ferroelectric tunnel barrier layer 120, and at the same time, the conductive protrusion F120 may be formed to extend from the interface between the ferroelectric tunnel barrier layer 120 and the second electrode layer 130 into the inside of the ferroelectric tunnel barrier layer 120 towards the first electrode layer 110. The conductive protrusion F120 does not contact the first electrode layer 110.

Thereafter, when a read operation is performed, a read voltage of a level that does not switch the first remanent polarization state may be applied between the first electrode layer 110 and the second electrode layer 130. The read voltage may have the same polarity as the first write voltage. When the read voltage is applied, tunneling may occur by the electrons formed in the electron accumulation region 111, thereby converting the state of the semiconductor device (1 of FIG. 1) into an on-state. The conductive protrusion F120 may reduce the tunneling width of the electrons, thereby increasing the tunneling efficiency of the electrons and increasing tunneling current density. As described with reference to FIG. 3 below, in an off-state, the conductive protrusion F120 may be completely or partially removed and the tunneling current density may be reduced. Accordingly, the conductive protrusion F120 may increase the on-off ratio of the semiconductor device 1.

Referring to FIG. 3, a predetermined second write voltage may be applied between the first electrode layer 110 and the second electrode layer 130 to perform a second write operation of semiconductor device 1. The second write voltage may have a level sufficient to switch the orientation of the first remanent polarization state stored in the ferroelectric tunnel barrier layer 120. The second write voltage may be a voltage configured such that the bias applied to the second electrode layer 130 has a positive polarity and the bias applied to the first electrode layer 110 has a negative polarity.

Referring to FIG. 3, by the application of the second write voltage, polarization having a second polarization orientation P2 may be formed in the ferroelectric tunnel barrier layer 120. The electric field generated by the polarization may form an electron deficiency region 112 in the inner region of the second electrode layer 130, adjacent to the interface between the ferroelectric tunnel barrier layer 120 and the second electrode layer 130. When the second write operation is performed, the electron accumulation region 111 formed by the first write operation may be converted into the electron deficiency region 112. In the electron deficiency region 112, a conduction band energy level Ec-130 of the second electrode layer 130 may be higher than the Fermi energy level Ef-130. Accordingly, the electron deficiency region 112 of the second electrode layer 130 cannot provide sufficient electron density for tunneling.

On the other hand, because the first electrode layer 110 has a higher electron density than the second electrode layer 130, the region of the first electrode layer 110, adjacent to the interface with the ferroelectric tunnel barrier layer 120, may be relatively less affected by the electric field generated by the polarization. Accordingly, in the region of the first electrode layer 110, adjacent to the ferroelectric tunnel barrier layer 120, an electron accumulation region might not be formed. That is, there may be no change in the energy band diagram in the region of the first electrode layer 110, adjacent to the ferroelectric tunnel barrier layer 120.

Referring to FIG. 3, when the second write voltage is applied between the first electrode layer 110 and the second electrode layer 130, the conductive protrusion F120 formed in the ferroelectric tunnel barrier layer 120 may be removed or may dissipate. The conductive protrusion F120 may decompose under the second write voltage as oxygen vacancies constituting the protrusion are diffused into the ferroelectric tunnel barrier layer 120. Although FIG. 3 illustrates that the conductive protrusion F120 is completely removed by the second write voltage, the present disclosure is not necessarily limited thereto.) In some embodiments, the conductive protrusion F120 may be partially removed. Under the second write voltage, the length of the remaining conductive protrusion F120 in the layer thickness direction may be shorter than the length of the conductive protrusion F120 of FIG. 2.

After forming the electron deficiency region 112 and completely or partially removing the conductive protrusion F120 through the application of the second write voltage, the second write operation may be completed by removing the second write voltage. After the second write voltage is removed, a second remanent polarization state having a second polarization orientation P2 may be maintained in the ferroelectric tunnel barrier layer 120. Accordingly, the electron deficiency region 112 may be maintained within the second electrode layer 130. Additionally, even after the second write voltage is removed, the conductive protrusion F120 may remain completely or partially removed. As the electron deficiency region 112 is formed, the tunneling width through which electrons have to tunnel for electrical conduction may increase from a first width W1, corresponding to the thickness of the ferroelectric tunnel barrier layer 120, to a second tunneling width W-r1.

As described above, by performing a second write operation, a second remanent polarization of a second polarization orientation P2 can be stored as second signal information in the ferroelectric tunnel barrier layer 120. At the same time, the conductive protrusion F120 extending from the interface between the ferroelectric tunnel barrier layer 120 and the second electrode layer 130 into the ferroelectric tunnel barrier layer 120 can be completely or partially removed.

Thereafter, when a read operation is performed by a read voltage, the tunneling current may be reduced and suppressed, thereby exhibiting an off-state.

In an embodiment of the present disclosure, in the off-state, the on-state conductive protrusion F120 may be completely or partially removed, so that the density of tunneling current may be relatively greatly reduced. As a result, according to an embodiment of the present disclosure, the on-off ratio of the semiconductor device can be increased by controlling the generation and removal of the conductive protrusion F120 within the ferroelectric tunneling barrier layer 120.

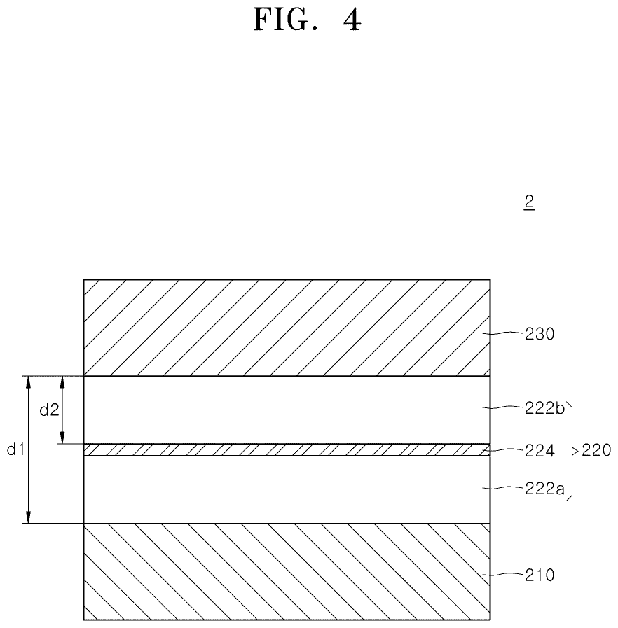

FIG. 4 is a cross-sectional view schematically illustrating a semiconductor device according to another embodiment of the present disclosure. Referring to FIG. 4, compared to a semiconductor device 1 described with reference to FIG. 1, a semiconductor device 2 may further include a protrusion control layer 224 arranged as a portion of a ferroelectric tunnel barrier layer 220.

The semiconductor device 2 may include a first electrode layer 210, the ferroelectric tunnel barrier layer 220 disposed on the first electrode layer 210, and a second electrode layer 230 disposed on the ferroelectric tunnel barrier layer 220. The first electrode layer 210 and the second electrode layer 230 may be substantially the same as the first electrode layer 110 and the second electrode layer 130 of the semiconductor device 1 described above with reference to FIG. 1. In an embodiment, the first electrode layer 210 may include an inert metal, and the second electrode layer 230 may include a conductive metal oxide.

The ferroelectric tunnel barrier layer 220 may include a first ferroelectric layer 222a, a protrusion control layer 224, and a second ferroelectric layer 222b that are sequentially disposed on the first electrode layer 210. The material of each of the first and second ferroelectric layers 222a and 222b may be substantially the same as the material of the ferroelectric tunnel barrier layer 120 of the semiconductor device 1 described above with reference to FIG. 1. In an embodiment, the first and second ferroelectric layers 222a and 222b may be formed of substantially the same material. That is, each of the first and second ferroelectric layers 222a and 222b may include, for example, hafnium oxide, zirconium oxide, hafnium zirconium oxide, or a combination of two or more thereof. As an example, the sum of the thicknesses of the first and second ferroelectric layers 222a and 222b may be about 1 nm to about 20 nm.

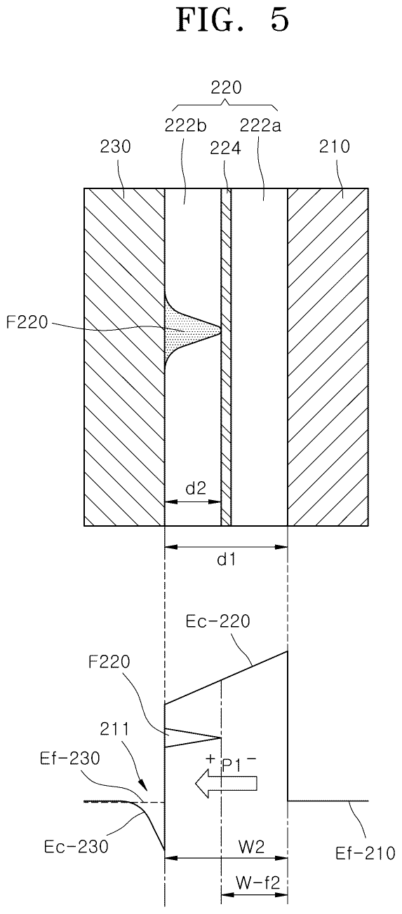

Referring to FIG. 4, the protrusion control layer 224 may be disposed on the first ferroelectric layer 222a and may serve to prevent the growth of the conductive protrusion F220, as will be described later with reference to FIG. 5. For example, the protrusion control layer 224 may include amorphous silicon oxide or amorphous aluminum oxide. The second ferroelectric layer 222b may be disposed on the protrusion control layer 224. The thickness of the protrusion control layer 224 may be less than the thickness of each of the first and second ferroelectric layers 222a and 222b.

In an embodiment, a distance d2 from the second electrode layer 230 to the protrusion control layer 224 may be ¼ to ½ of a distance d1 between the first electrode layer 210 and the second electrode layer 230. In this case, the thickness of the second ferroelectric layer 222b may be less than the thickness of the first ferroelectric layer 222a.

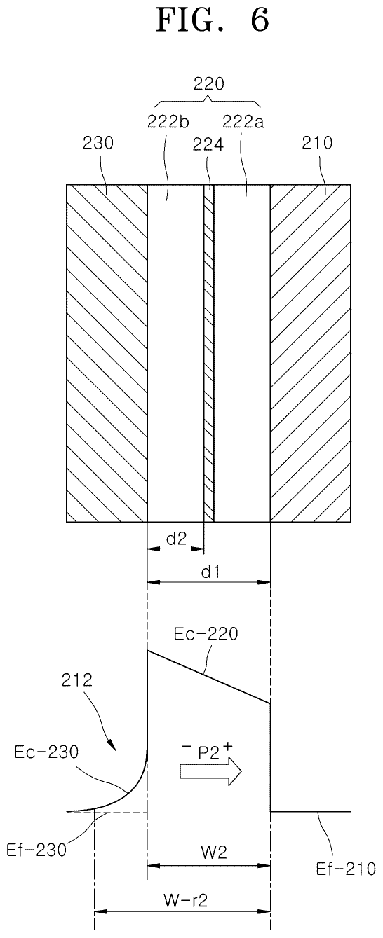

FIGS. 5 and 6 are views schematically illustrating an operation of a semiconductor device according to an embodiment of the present disclosure. A method of operating the semiconductor device may be described using a semiconductor device 2 of FIG. 4. Specifically, FIG. is a view illustrating a first write operation of converting the state of the semiconductor device 2 into an electrical on-state. FIG. 5 may schematically illustrate an internal structure and energy band diagram of the semiconductor device 2 after the first write operation is completed. FIG. 6 is a view illustrating a second write operation of converting the state of the semiconductor device 2 into an electrical off-state. FIG. 6 may schematically illustrate the internal structure and energy band diagram of the semiconductor device 2 after the second write operation is completed.

Referring to FIG. 5, the first write operation of the semiconductor device 2 may be performed by applying a predetermined first write voltage. The first write voltage may be a voltage configured such that the bias applied to a second electrode layer 230 has a negative polarity and the bias applied to a first electrode layer 210 has a positive polarity.

Through the application of the first write voltage, polarization having a first polarization orientation P1 may be formed in a ferroelectric tunnel barrier layer 220. The electric field generated by the polarization may induce electrons to an inner region of the second electrode layer 230, adjacent to the interface between the ferroelectric tunnel barrier layer 220 and the second electrode layer 230, to form an electron accumulation region 211.

In addition, when the first write voltage is applied between the first electrode layer 210 and the second electrode layer 230, oxygen vacancies with positive charges may accumulate in the ferroelectric tunnel barrier layer 220 to form a conductive protrusion F220. Specifically, when the first write voltage is applied, the conductive protrusion F220 may grow from the interface between the second electrode layer 230 and a second ferroelectric layer 222b to extend inside of the second ferroelectric layer 222b toward a protrusion control layer 224. The growth of the conductive protrusion F220 may be stopped after the conductive protrusion F220reaches the protrusion control layer 224.

As a result, the growth of the conductive protrusion F220 may be effectively controlled. The protrusion control layer 224 may serve as a barrier that prevents the conductive protrusion F220 from growing into a first ferroelectric layer 222a. Accordingly, the growth of the conductive protrusion F220 may be limited and restricted to within the second ferroelectric layer 222b of the ferroelectric tunnel barrier layer 220.

In an embodiment, because a distance d2 from the second electrode layer 230 to the protrusion control layer 224 is ¼ to ½ of a distance d1 between the first electrode layer 210 and the second electrode layer 230, the length of the conductive protrusion F220 along the thickness direction of the ferroelectric tunnel barrier layer 220 may be ¼ to ½ of the distance d1 between the first electrode layer 210 and the second electrode layer 230.

In FIG. 5, shapes of a Fermi energy level Ef-230 and a conduction band energy level Ec-230 of the second electrode layer 230, a shape of a conduction band energy level Ec-220 of the ferroelectric tunnel junction layer 220, and a shape of a Fermi energy level Ef-210 of the first electrode layer 210 are substantially the same as shapes of the Fermi energy level Ef-130 and the conduction band energy level Ec-130 of the second electrode layer 130, a shape of the conduction band energy level Ec-120 of the ferroelectric tunnel junction layer 120, and a shape of the Fermi energy level Ef-110 of the first electrode layer 110 as shown in FIG. 2. Due to the conductive protrusion F220, the tunneling width of electrons that are tunneled for electrical conduction may be reduced from a first width W2, corresponding to the thickness of the ferroelectric tunnel barrier layer 220, to a first tunneling width W-f2.

Referring to FIG. 6, a predetermined second write voltage may be applied between the first electrode layer 210 and the second electrode layer 230 to perform a second write operation of the semiconductor device 2. The second write voltage may be a voltage configured such that the bias applied to the second electrode layer 230 has a positive polarity and the bias applied to the first electrode layer 210 has a negative polarity.

Referring to FIG. 6, by the application of the second write voltage, polarization having a second polarization orientation P2 may be formed in the ferroelectric tunnel barrier layer 220. The electric field generated by the polarization may form an electron deficiency region 212 in the inner region of the second electrode layer 230, adjacent to the interface between the ferroelectric tunnel barrier layer 220 and the second electrode layer 230.

Additionally, when the second write voltage is applied between the first electrode layer 210 and the second electrode layer 230, the conductive protrusion F220 formed in the second ferroelectric layer 222b may be removed or may dissipate. The conductive protrusion F220 may decompose as oxygen vacancies constituting the conductive protrusion F220 are discharged into the second ferroelectric layer 222b under the second write voltage. While FIG. 6 illustrates that the conductive protrusion F220 is completely removed by the second write voltage, the present disclosure is not necessarily limited thereto. In some embodiments, the conductive protrusion F220 may be partially removed. As the conductive protrusion F220 dissipates or is partially removed, the length of the remaining conductive protrusion F220 in the layer thickness direction may be shorter than the length of the conductive protrusion F220 of FIG. 5. In FIG. 6, shapes of a Fermi energy level Ef-230 and a conduction band energy level Ec-230 of the second electrode layer 230, a shape of a conduction band energy level Ec-220 of the ferroelectric tunnel junction layer 220, and a shape of a Fermi energy level Ef-210 of the first electrode layer 210 are substantially the same as shapes of the Fermi energy level Ef-130 and the conduction band energy level Ec-130 of the second electrode layer 130, a shape of the conduction band energy level Ec-120 of the ferroelectric tunnel junction layer 120, and a shape of the Fermi energy level Ef-110 of the first electrode layer 110 as shown in FIG. 3. As the electron deficiency region 212 is formed, the tunneling width through which electrons have to tunnel for electrical conduction may increase from a first width W2, corresponding to the thickness of the ferroelectric tunnel barrier layer 120, to a second tunneling width W-r2.

As described above, according to an embodiment of the present disclosure, when first and second write operations are performed, the location of the conductive protrusion F220 may be limited to the second ferroelectric layer 222b of the ferroelectric tunneling barrier layer 220. Accordingly, the reliability of the on-off operation of the semiconductor device 2 can be improved.

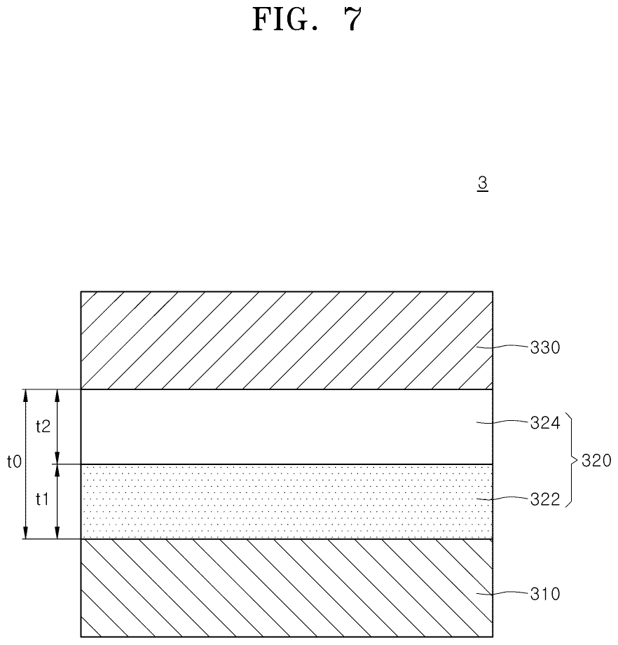

FIG. 7 is a cross-sectional view schematically illustrating a semiconductor device according to another embodiment of the present disclosure. Referring to FIG. 7, compared to a semiconductor device 1 described with reference to FIG. 1, a semiconductor device 3 may have a ferroelectric tunnel barrier layer with a different configuration.

The semiconductor device 3 may include a first electrode layer 310, a ferroelectric tunnel barrier layer 320 disposed on the first electrode layer 310, and a second electrode layer 330 disposed on the ferroelectric tunnel barrier layer 320. The first electrode layer 310 and the second electrode layer 330 may be substantially the same as a first electrode layer 110 and a second electrode layer 120 of the semiconductor device 1 described above with reference to FIG. 1. In an embodiment, the first electrode layer 310 may include an inert metal, and the second electrode layer 330 may include a conductive metal oxide.

The ferroelectric tunnel barrier layer 320 may include a first ferroelectric portion 322 and a second ferroelectric portion 324, which are sequentially disposed on the first electrode layer 310. The first ferroelectric portion 322 may include oxygen vacancies of a first concentration. The second ferroelectric portion 324 may include oxygen vacancies of a second concentration higher than the first concentration. As illustrated in FIG. 7, the second ferroelectric portion 324 may be disposed closer to the second electrode layer 330 than the first ferroelectric portion 322.

In an embodiment, the first and second ferroelectric portions 322 and 324 may be formed of substantially the same material, with only the concentration of oxygen vacancies being different. That is, each of the first and second ferroelectric portions 322 and 324 may include, for example, hafnium oxide, zirconium oxide, hafnium zirconium oxide, or a combination of two or more thereof. In an embodiment, when forming the first ferroelectric portion 322 on the first electrode layer 310, an oxygen source may be supplied. The oxygen source may then be reduced when forming the second ferroelectric portion 324 on the first ferroelectric portion 322. As a result, an oxygen deficiency may be generated within the second ferroelectric portion 324, and the concentration of oxygen vacancies in the second ferroelectric portion 324 may be increased compared to the first ferroelectric portion 322. As an example, the first and second ferroelectric portions 322 and 324 may be formed by applying an atomic layer deposition (ALD) method.

In an embodiment, a thickness t2 of the second ferroelectric portion 324 may be less than a thickness t1 of the first ferroelectric portion 322. The thickness t2 of the second ferroelectric portion 324 may be ¼ to ½ of a thickness to of the ferroelectric tunnel barrier layer 320.

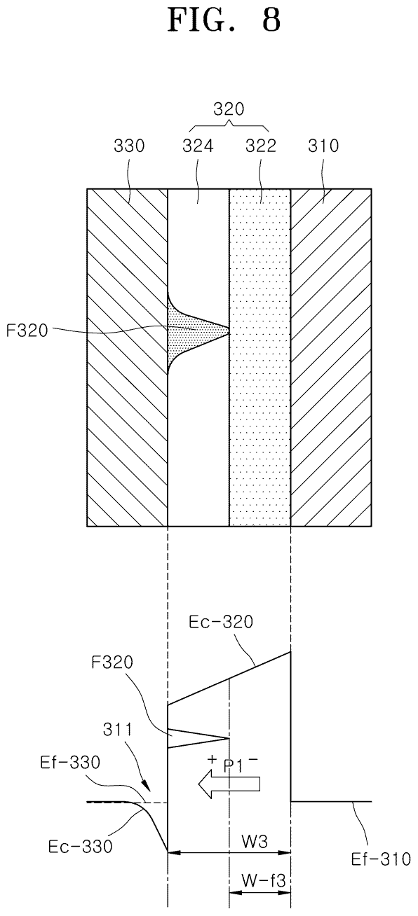

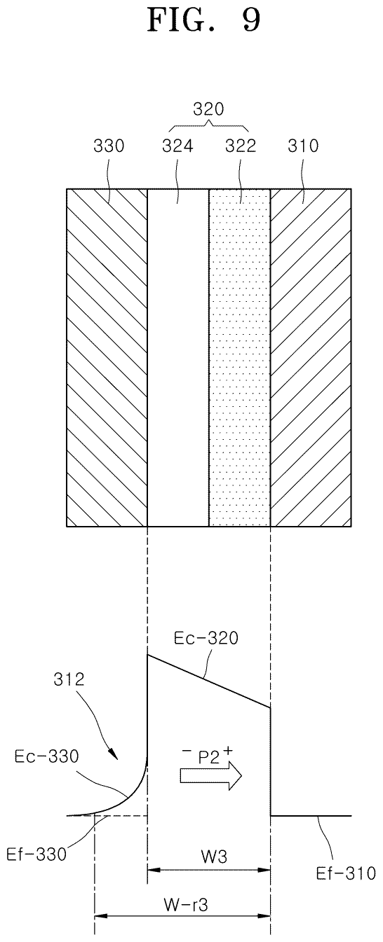

FIGS. 8 and 9 are views schematically illustrating an operation of a semiconductor device according to an embodiment of the present disclosure. A method of operating the semiconductor device may be described using a semiconductor device 3 of FIG. 7. FIG. 8 is a view illustrating a first write operation of converting the state of the semiconductor device 3 into an electrical on-state. FIG. 8 may schematically illustrate an internal structure and energy band diagram of the semiconductor device 3 after the first write operation is completed. FIG. 9 is a view illustrating a second write operation of converting the state of the semiconductor device 3 into an electrical off-state. FIG. 9 may schematically illustrate the internal structure and energy band diagram of the semiconductor device 3 after the second write operation is completed.

Referring to FIG. 8, a first write voltage may be applied between a first electrode layer 310 and a second electrode layer 330 to perform the first write operation of the semiconductor device 3. The first write voltage may be a voltage configured such that the bias applied to the second electrode layer 330 has a negative polarity and the bias applied to the first electrode layer 310 has a positive polarity.

Referring to FIG. 8, by the application of the first write voltage, polarization having a first polarization orientation P1 may be formed inside the ferroelectric tunnel barrier layer 320. The electric field generated by the polarization may induce electrons in an inner region of the second electrode layer 330, adjacent to the interface between the ferroelectric tunnel barrier layer 320 and the second electrode layer 330, to form an electron accumulation region 311.

In addition, when the first write voltage is applied between the first electrode layer 310 and the second electrode layer 330, oxygen vacancies having a positive polarity may accumulate inside the ferroelectric tunnel barrier layer 320 to form a conductive protrusion F320. The conductive protrusion F320 may grow inside of a second ferroelectric portion 324 to extend from the interface between the second electrode layer 330 and the second ferroelectric portion 324 toward the a first ferroelectric portion 322.

In an embodiment, the conductive protrusion F320 may be formed in the second ferroelectric portion 324 with a higher concentration of oxygen vacancies. The conductive protrusion F320 may stop growing after reaching the first ferroelectric portion 322, which has a relatively lower concentration of oxygen vacancies. In an embodiment, referring to FIG. 7, a length of the conductive protrusion F320 along the thickness direction of the ferroelectric tunnel barrier layer 320 may correspond to a thickness t2 of the second ferroelectric portion 324.

As described above, the growth of the conductive protrusion F320 can be effectively controlled by using a difference in the concentration of oxygen vacancies between the first and second ferroelectric portions 322 and 324.

In FIG. 8, shapes of a Fermi energy level Ef-330 and a conduction band energy level Ec-330 of the second electrode layer 330, a shape of a conduction band energy level Ec-320 of the ferroelectric tunnel junction layer 320, and a shape of a Fermi energy level Ef-310 of the first electrode layer 310 are substantially the same as shapes of the Fermi energy level Ef-130 and the conduction band energy level Ec-130 of the second electrode layer 130, a shape of the conduction band energy level Ec-120 of the ferroelectric tunnel junction layer 120, and a shape of the Fermi energy level Ef-110 of the first electrode layer 110 as shown in FIG. 2. Due to the conductive protrusion F320, the tunneling width of electrons that are tunneled for electrical conduction may be reduced from a first width W3, corresponding to the thickness of the ferroelectric tunnel barrier layer 320, to a first tunneling width W-f2.

Referring to FIG. 9, by the application of a second write voltage, polarization having a second polarization orientation P2 may be formed in the ferroelectric tunnel barrier layer 320. The second write voltage may be a voltage configured such that the bias applied to the second electrode layer 330 has a positive polarity and the bias applied to the first electrode layer 310 has a negative polarity. The electric field generated by the polarization may form an electron deficiency region 312 in the inner region of the second electrode layer 330, adjacent to the interface between the ferroelectric tunnel barrier layer 320 and the second electrode layer 330.

In addition, when the second write voltage is applied between the first electrode layer 310 and the second electrode layer 330, the conductive protrusion F320 formed in the second ferroelectric portion 324 may be removed or may dissipate. The conductive protrusion F320 may decompose by the discharge of oxygen vacancies into the second ferroelectric portion 324 under the second write voltage. Although FIG. 9 illustrates that the conductive protrusion F320 is completely removed by the second write voltage, the present disclosure is not limited thereto. In some embodiments, the conductive protrusion F320 may be partially removed. Under the second write voltage, the length in the layer thickness direction of the remaining conductive protrusion F320 may be shorter than that of the conductive protrusion F320 of FIG. 8.

In FIG. 9, shapes of a Fermi energy level Ef-330 and a conduction band energy level Ec-330 of the second electrode layer 330, a shape of a conduction band energy level Ec-320 of the ferroelectric tunnel junction layer 320, and a shape of a Fermi energy level Ef-310 of the first electrode layer 310 are substantially the same as shapes of the Fermi energy level Ef-130 and the conduction band energy level Ec-130 of the second electrode layer 130, a shape of the conduction band energy level Ec-120 of the ferroelectric tunnel junction layer 120, and a shape of the Fermi energy level Ef-110 of the first electrode layer 110 as shown in FIG. 3. As the electron deficiency region 312 is formed, the tunneling width through which electrons have to tunnel for electrical conduction may increase from a first width W3, corresponding to the thickness of the ferroelectric tunnel barrier layer 320, to a second tunneling width W-r3.

As described above, according to an embodiment of the present disclosure, when first and second write operations are performed, the location of a conductive protrusion F320 may be limited to a second ferroelectric portion 324 of ferroelectric tunneling barrier layer 320, thereby improving the reliability of the on-off operation of the semiconductor device 3.

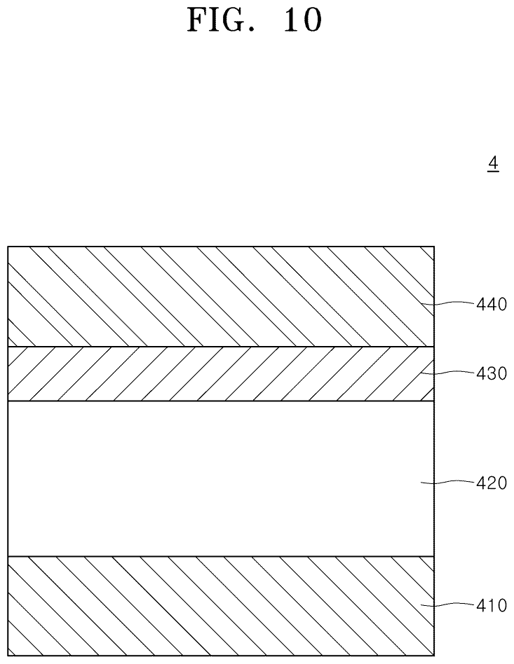

FIG. 10 is a cross-sectional view schematically illustrating a semiconductor device according to yet another embodiment of the present disclosure. A semiconductor device 4 may further include an oxygen reservoir layer 430, compared to a semiconductor device 1 described with reference to FIG. 1.

The semiconductor device 4 may include a first electrode layer 410, a ferroelectric tunnel barrier layer 420 disposed on the first electrode layer 410, the oxygen reservoir layer 430 disposed on the ferroelectric tunnel barrier layer 420, and a second electrode layer 440 disposed on the oxygen reservoir layer 430.

The first electrode layer 410 may be substantially the same as the first electrode layer 110 of the semiconductor device 1 described above with reference to FIG. 1. The ferroelectric tunnel barrier layer 420 may be substantially the same as the ferroelectric tunnel barrier layer 120 of the semiconductor device 1 described above with reference to FIG. 1.

The oxygen reservoir layer 430 may include a metal oxide that does not satisfy a stoichiometric ratio. For example, the oxygen reservoir layer 430 may include titanium oxide, tantalum oxide, or a combination thereof. The oxygen reservoir layer 430 may exchange oxygen ions with the ferroelectric tunnel barrier layer 420.

The second electrode layer 440 may be disposed on the oxygen reservoir layer 430. The second electrode layer 440 may include a conductive material. In an embodiment, the second electrode layer 440 may be formed of substantially the same material as the first electrode layer 410. In another embodiment, the second electrode layer 440 may be formed of substantially the same material as a second electrode layer 130 of the semiconductor device 1 described above with reference to FIG. 1.

In an embodiment, the first and second write operations of the semiconductor device 4 may be substantially the same as the first and second write operations of the semiconductor device 1 described above with reference to FIG. 1. However, in the semiconductor device 4, when compared to the semiconductor 1 of FIG. 1, the oxygen reservoir layer 430 may be provided separately, and thus, the generation of the conductive protrusion may be enhanced during the first write operation, and the decomposition of the conductive protrusion may be enhanced during the second write operation. The conductive protrusion may be arranged to extend from the interface between the oxygen reservoir layer 430 and the ferroelectric tunnel barrier layer 420, within the inside of the ferroelectric tunnel barrier layer 420, towards the first electrode layer 410.

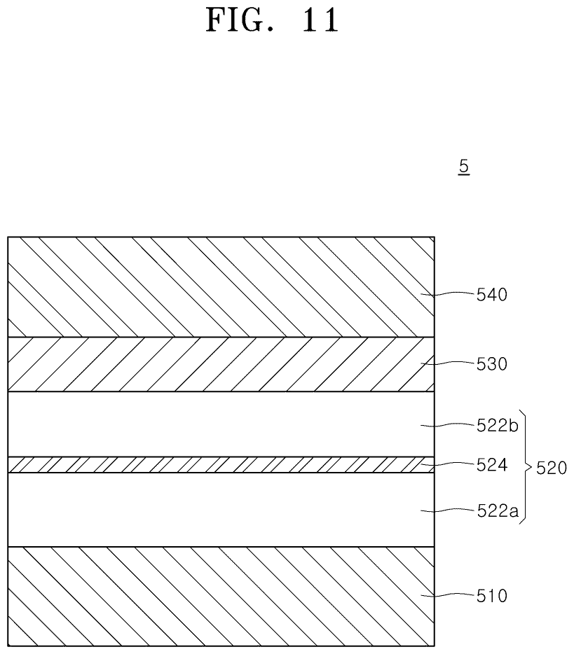

FIG. 11 is a cross-sectional view schematically illustrating a semiconductor device according to yet another embodiment of the present disclosure. Referring to FIG. 11, a semiconductor device 5 may further include a protrusion control layer 524 disposed as a portion of a ferroelectric tunnel barrier layer 520, compared to a semiconductor device 4 described with reference to FIG. 10.

The semiconductor device 5 may include a first electrode layer 510, the ferroelectric tunnel barrier layer 520 disposed on the first electrode layer 510, an oxygen reservoir layer 530 disposed on the ferroelectric tunnel barrier layer 520, and a second electrode layer 540 disposed on the oxygen reservoir layer 530. The configurations of the first electrode layer 510, the oxygen reservoir layer 530, and the second electrode layer 540 may be substantially the same as the configurations of a first electrode layer 410, an oxygen reservoir layer 430, and a second electrode layer 440 of a semiconductor device 4 described with reference to FIG. 10.

The ferroelectric tunnel barrier layer 520 may include a first ferroelectric layer 522a, the protrusion control layer 524, and a second ferroelectric layer 522b that are sequentially disposed on the first electrode layer 510. The configurations of the first ferroelectric layer 522a, the protrusion control layer 524, and the second ferroelectric layer 522b may be substantially the same as the configurations of the first ferroelectric layer 222a, the protrusion control layer 224, and the second ferroelectric layer 222b of a semiconductor device 2 described with reference to FIG. 4, and accordingly, detailed descriptions are omitted.

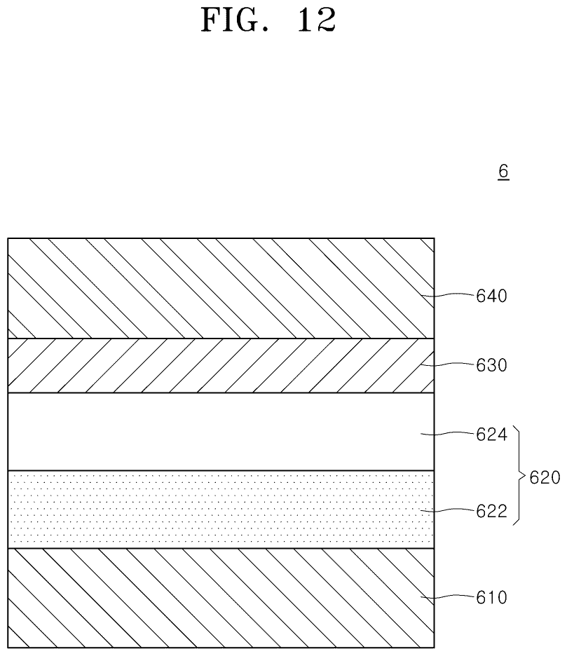

FIG. 12 is a cross-sectional view schematically illustrating a semiconductor device according to still another embodiment of the present disclosure. When compared to a semiconductor device 4 described with reference to FIG. 10, a semiconductor device 6 may have a different configuration of a ferroelectric tunnel barrier layer.

The semiconductor device 6 may include a first electrode layer 610, a ferroelectric tunnel barrier layer 620 disposed on the first electrode layer 610, an oxygen reservoir layer 630, and a second electrode layer 640 disposed on the oxygen reservoir layer 630. The configurations of the first electrode layer 610, the oxygen reservoir layer 630, and the second electrode layer 640 may be substantially the same as the configurations of a first electrode layer 410, an oxygen reservoir layer 430, and a second electrode layer 440 of a semiconductor device 4 described with reference to FIG. 10, and accordingly, detailed descriptions will be omitted.

The ferroelectric tunnel barrier layer 620 may include a first ferroelectric portion 622 and a second ferroelectric portion 624 that are sequentially disposed on the first electrode layer 610. The configurations of the first and second ferroelectric portions 622 and 624 may be substantially the same as the configurations of the first and second ferroelectric portions 322 and 324 of the semiconductor device 3 described with reference to FIG. 7, and accordingly, detailed descriptions will be omitted.

Referring to FIG. 12, the second ferroelectric portion 624 may be disposed to contact the oxygen reservoir layer 630. Accordingly, the conductive protrusion generated in connection with an operation of the semiconductor device 6 may extend from an interface of the oxygen reservoir layer 630 and the second ferroelectric portion 624 into the interior of the second ferroelectric portion 624 towards the first ferroelectric portion 622.

Concepts have been disclosed in conjunction with some embodiments as described above. Those skilled in the art will appreciate that various modifications, additions, and substitutions are possible, without departing from the scope and spirit of the present disclosure. Accordingly, embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A semiconductor device comprising:
a first electrode layer;
a ferroelectric tunnel barrier layer disposed over the first electrode layer, the ferroelectric tunnel barrier layer including oxygen vacancies; and
a second electrode layer disposed over the ferroelectric tunnel barrier layer and including a metal oxide,
wherein the second electrode layer has a relatively low density of conducting carriers, compared to the first electrode layer.

2. The semiconductor device of claim 1, further comprising a conductive protrusion extending from an interface of the second electrode layer and the ferroelectric tunnel barrier layer into the ferroelectric tunnel barrier layer,
wherein the conductive protrusion comprises oxygen vacancies.

3. The semiconductor device of claim 2, wherein the conductive protrusion does not contact the first electrode layer.

4. The semiconductor device of claim 1, wherein the first electrode layer comprises an inert metal.

5. The semiconductor device of claim 1, wherein the metal oxide comprises at least one selected from ruthenium oxide (RuO₂), iridium oxide (IrO₂), platinum oxide (PtO₂), strontium ruthenium oxide (SrRuO₃), metallic perovskite oxide, and conducting pyrochlore oxide.

6. The semiconductor device of claim 1, wherein the ferroelectric tunnel barrier layer comprises at least one of hafnium oxide, zirconium oxide, and hafnium zirconium oxide.

7. The semiconductor device of claim 1, wherein the ferroelectric tunnel barrier layer comprises:
a first ferroelectric layer disposed adjacent to the first electrode layer;
a second ferroelectric layer disposed adjacent to the second electrode layer; and
a protrusion control layer disposed between the first ferroelectric layer and the second ferroelectric layer.

8. The semiconductor device of claim 7, wherein a distance from the second electrode layer to the protrusion control layer is ¼ to ½ of a distance between the first electrode layer and the second electrode layer.

9. The semiconductor device of claim 7, wherein the protrusion control layer comprises amorphous silicon oxide or amorphous aluminum oxide.

10. The semiconductor device of claim 1,
wherein the ferroelectric tunnel barrier layer comprises:
a first ferroelectric portion including oxygen vacancies of a first concentration; and
a second ferroelectric portion including oxygen vacancies of a second concentration higher than the first concentration, and
wherein the second ferroelectric portion is disposed closer to the second electrode layer than the first ferroelectric portion.

11. The semiconductor device of claim 10, wherein the ferroelectric tunnel barrier layer comprises a conductive protrusion disposed in the second ferroelectric portion.

12. The semiconductor device of claim 10, wherein a thickness of the second ferroelectric portion is ¼ to ½ of a thickness of the ferroelectric tunnel barrier layer.

13. A semiconductor device comprising:
a first electrode layer;
a ferroelectric tunnel barrier layer disposed over the first electrode layer, the ferroelectric tunnel barrier layer including oxygen vacancies;
an oxygen reservoir layer disposed over the ferroelectric tunnel barrier layer; and
a second electrode layer disposed over the oxygen reservoir layer.

14. The semiconductor device of claim 13, further comprising a conductive protrusion extending from the oxygen reservoir layer to the ferroelectric tunnel barrier layer,
wherein the conductive protrusion comprises oxygen vacancies.

15. The semiconductor device of claim 14, wherein the conductive protrusion does not contact the first electrode layer.

16. The semiconductor device of claim 13,
wherein the oxygen reservoir layer comprises a metal oxide that does not satisfy a stoichiometric ratio, and
wherein the oxygen reservoir layer comprises at least one selected from titanium oxide and tantalum oxide.

17. The semiconductor device of claim 13, wherein the ferroelectric tunnel barrier layer comprises:
a first ferroelectric layer disposed adjacent to the first electrode layer;
a second ferroelectric layer disposed adjacent to the oxygen reservoir layer; and
a protrusion control layer disposed between the first ferroelectric layer and the second ferroelectric layer,
wherein the second ferroelectric layer comprises a conductive protrusion including oxygen vacancies.

18. The semiconductor device of claim 17, wherein the protrusion control layer comprises amorphous silicon oxide or amorphous aluminum oxide.

19. The semiconductor device of claim 13,
wherein the ferroelectric tunnel barrier layer includes:
a first ferroelectric portion with a relatively low concentration of oxygen vacancies; and
a second ferroelectric portion with a relatively high concentration of oxygen vacancies, and
wherein the second ferroelectric portion is disposed adjacent to the second electrode layer.

20. The semiconductor device of claim 19, wherein the ferroelectric tunnel barrier layer includes a conductive protrusion disposed in the second ferroelectric portion.

21. A semiconductor device comprising:
a first electrode layer;
a ferroelectric tunnel barrier layer disposed over the first electrode layer; and
a second electrode layer including a metal oxide disposed over the ferroelectric tunnel barrier layer,
wherein the ferroelectric tunnel barrier layer includes:
a first ferroelectric portion including oxygen vacancies of a first concentration; and
a second ferroelectric portion including oxygen vacancies of a second concentration higher than the first concentration.

22. The semiconductor device of claim 21, wherein the ferroelectric tunnel barrier layer comprises a conductive protrusion disposed in the second ferroelectric portion, and
wherein the conductive protrusion comprises oxygen vacancies.

23. The semiconductor device of claim 21,
wherein the first ferroelectric portion is disposed adjacent to the first electrode layer, and
wherein the second ferroelectric portion is disposed adjacent to the second electrode layer.

24. The semiconductor device of claim 21, wherein a thickness of the second ferroelectric portion is ¼ to ½ of a thickness of the ferroelectric tunnel barrier layer.

25. The semiconductor device of claim 21, further comprising an oxygen reservoir layer disposed between the first electrode layer and the second electrode layer and in contact with the second ferroelectric portion.
